(19) United States
(12) Patent Application Publication
(10) Pub. No.: US 2025/0138048 A1
(43) Pub. Date: May 1, 2025

(54) TEST MODULE FOR TESTING IMAGE SENSOR AND TEST SYSTEM INCLUDING THE TEST MODULE

(71) Applicant: Samsung Electronics Co., Ltd., Suwon-si (KR)

(72) Inventors: Insang SONG, Suwon-si (KR); Kihyun KWON, Suwon-si (KR); Gunwoo RYU, Suwon-si (KR); Jaehyun BYUN, Suwon-si (KR); Kyoungsoo SON, Suwon-si (KR)

(73) Assignee: Samsung Electronics Co., Ltd., Suwon-si (KR)

(21) Appl. No.: 18/916,304

(22) Filed: Oct. 15, 2024

(30) Foreign Application Priority Data
Oct. 25, 2023 (KR) 10-2023-0144175

(51) Int. Cl. G01R 1/04; G01R 31/28

(52) U.S. Cl. CPC G01R 1/0408; G01R 31/2825

(57) ABSTRACT

Provided is a test module for testing the performance of an image sensor, the test module including a test board having an area greater than an area of the image sensor and configured to be coupled to the image sensor, and a connector electrically connected to the image sensor and configured to transmit an electrical signal received from the image sensor to a test socket, wherein the test board includes a dummy region of which an outer perimeter corresponds to a perimeter of the test board and configured to be electrically cut off from the image sensor, and a cut-off region formed corresponding to an inner perimeter of the dummy region, located between the dummy region and the image sensor, and configured to electrically cut off the dummy region from the image sensor.

### CROSS-REFERENCE TO RELATED APPLICATION

This application is based on and claims priority under 35 U.S.C. § 119 to Korean Patent Application No. 10-2023-0144175, filed on Oct. 25, 2023, in the Korean Intellectual Property Office, the disclosure of which is incorporated by reference herein in its entirety.

### BACKGROUND

Example embodiments relate to a test module, and more particularly, to a test module for testing the performance of an image sensor and/or a test system including the test module.

Image sensors have recently become essential in electronic devices, such as smartphones and/or tablets, for capturing still images and filming videos. Accordingly, the need to improve the performance of image sensors and to accurately and quickly test the performance of image sensors is increasing.

A plastic leadless chip carrier (PLCC) may be used to test the performance of an image sensor. When testing the performance of an image sensor based on the PLCC, the test accuracy may be reduced because the electrical and/or optical environment of an electronic device to which the image sensor is applied is not reflected in the test. When using a printed circuit board (PCB) containing the image sensor and passive elements included in the electronic device to reflect in the test the electrical environment of the electronic device to which the image sensor is applied, manufacturing a test socket combinable with the PCB containing the image sensor and the passive elements is costly and time-consuming.

### SUMMARY

Various example embodiments may provide a test module and/or a test system including the same capable of testing the performance of an image sensor by reflecting in the test the electrical and optical environment of an electronic device to which the image sensor is applied based on the test module with a constant area and shape, and capable of testing the performance of different image sensors through one test socket, thereby reducing the time and/or the cost required to test the performance of the image sensors.

According to some example embodiments, there is provided a test module configured to test the performance of an image sensor, the test module including a test board having an area greater than that of the image sensor and configured to be coupled to the image sensor, and a connector electrically connected to the image sensor and configured to transmit an electrical signal received from the image sensor to a test socket. The test board includes a dummy region of which outer perimeter corresponds to a perimeter of the test board and configured to be electrically cut off from the image sensor, and a cut-off region corresponding to an inner perimeter of the dummy region, between the dummy region and the image sensor, and configured to electrically cut off the dummy region from the image sensor.

Alternatively or additionally according to various example embodiments, there is provided a test system including a first test module including a first test board and configured to be coupled to a first image sensor having a first area through the first test board, and a test socket including a coupling region having a recessed structure corresponding to the shape of the first test module, and configured to be coupled to the first test module through the coupling region. The first test board includes a first dummy region corresponding to the perimeter of the first test board, a first printed circuit board (PCB) region configured to be coupled to the first image sensor, and a first cut-off region between the first dummy region and the first PCB region and configured to electrically cut off the first dummy region from the first PCB region.

Alternatively or additionally according to various example embodiments, there is provided a test module for testing the performance of an image sensor, the test module including a test board having an area greater than that of the image sensor and configured to be coupled to the image sensor, and a connector electrically connected to the image sensor and configured to transmit an electrical signal received from the image sensor to a test socket. The test board includes a PCB region configured to be coupled to the image sensor, and a cut-off region configured to electrically cut off the PCB region from the other region of the test board than the PCB region.

### BRIEF DESCRIPTION OF THE DRAWINGS

Embodiments will be more clearly understood from the following detailed description taken in conjunction with the accompanying drawings in which:

FIG. 1 is a block diagram of a test system according to various example embodiments;

FIG. 2 is a perspective view of a test module according to various example embodiments;

FIG. 3 is a perspective view of a test module according to various example embodiments;

FIG. 4 is a perspective view of a test socket according to various example embodiments;

FIG. 5 is a plan view of a test board according to various example embodiments; and

FIG. 6 is a flowchart of a method of manufacturing a test module according to various example embodiments.

### DETAILED DESCRIPTION

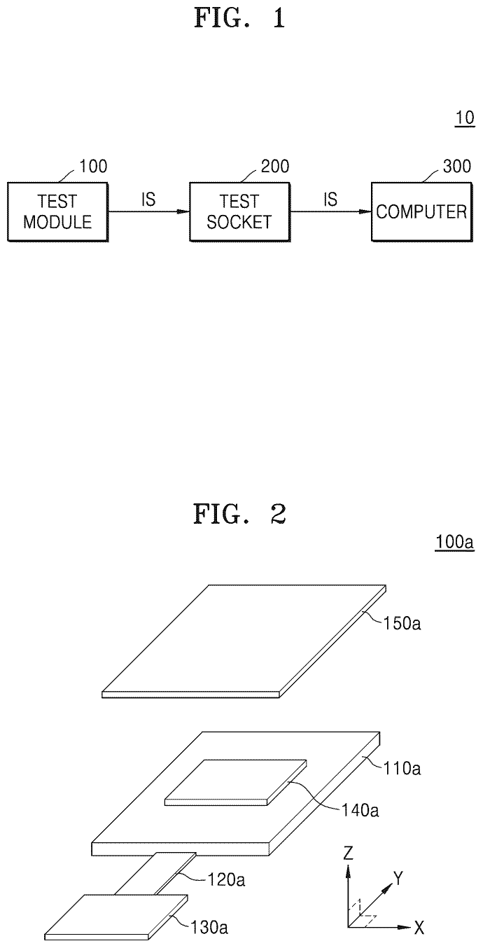

FIG. 1 is a block diagram of a test system according to various example embodiments.

Referring to FIG. 1, a test system 10 according to inventive concepts may include a test module 100, a test socket 200, and a computer 300.

The test module 100 may be coupled to an image sensor. For example, the image sensor may be coupled to a test board included in the test module 100. The test board is described below with reference to FIG. 2. The image sensor may be or may include a charge-coupled device (CCD) image sensor and/or a complementary metal oxide semiconductor (CMOS) image sensor, but example embodiments are not limited thereto.

The test module 100 may be electrically coupled to the image sensor through the test board. The image sensor coupled to the test module 100 may generate an image signal IS. The test system 10 according to inventive concepts may test the performance of the image sensor based on the image signal IS generated from the image sensor coupled to the test module 100. The image signal IS generated from the image sensor may be transmitted to the test socket 200 through the test module 100. For example, the test module 100 may be physically and/or electrically coupled to the image sensor through the test board, as described below. In inventive concepts, the expression “physically coupled” may mean or indicate that one component is coupled and fixed to another component, and the expression “electrically coupled” may mean or indicate that the combined components may exchange electrical signals with each other.

The test socket 200 may receive the image signal IS from the test module 100. The test socket 200 may transmit the image signal IS received from the test module 100 to the computer 300. The test socket 200 may be coupled to test module 100. The test system 10 including the test socket 200 according to inventive concepts may test the performance of image sensors based on the test module 100 having a constant area and shape. For example, the test system 10 may use the test module 100 having a constant area and shape for a plurality of image sensors having different areas and shapes to test the performance of the plurality of different image sensors based on one test socket 200. The test socket 200 is described in more detail below with reference to FIG. 4.

The computer 300 may refer to a device including a processor capable of performing calculation operations according to commands, such as a personal computer (PC), but is not limited thereto. The computer 300 according to inventive concepts may refer to various devices including a processor for testing image sensors based on the image signal IS received from the test socket 200. In some example embodiments, the computer 300 may be or may include one or more of a desktop, a laptop, or a mobile device such as a tablet and/or a mobile phone. In some example embodiments, the test socket 200 may communicate with the computer 300 through a wired connection and/or through a wireless connection; example embodiments are not limited thereto.

The image sensors may be included in various electronic devices. For example, the image sensors may be mounted on electronic devices, such as one or more of cameras, smartphones, wearable devices, Internet of Things (IoT), tablet PC, personal digital assistant (PDA), portable multimedia player (PMP), navigation devices, and the like. Additionally or alternatively, the image sensors may be mounted on electronic devices that are included as components in vehicles, furniture, manufacturing facilities, doors, and various measuring devices.

The image sensors may have different areas and/or different shapes depending on the electronic devices to which the image sensors are applied. For example, an image sensor applied to a smartphone and an image sensor applied to a tablet PC may have different areas and/or shapes, depending on one or more of the performance, purpose, and/or configuration of the electronic devices. Accordingly, to test the performance of image sensors having different areas and/or shapes, the area and/or shape of the test module may vary. However, since the test module 100 according to inventive concepts has a constant area and shape regardless of the area and shape of image sensors, the performance of a plurality of different image sensors may be tested based on one test socket 200. Accordingly, since there is no need or expectation to separately manufacture a test socket for each of the plurality of image sensors, the cost and/or the time required to test the performance of the image sensor may be reduced or improved upon.

The electronic device to which the image sensor is applied may include a plurality of passive elements such as but not limited to resistors and/or capacitors and/or inductors and/or memristors. The plurality of passive elements included in the electronic device may affect the operation of the image sensor. For example, a capacitor adjacent to the image sensor may affect the image signal IS generated by the image sensor. Therefore, to accurately or more accurately test the performance of the image sensor, it is necessary or desirable to reflect the influence of the passive elements. The test module 100 according to inventive concepts may include at least one of the plurality of passive elements included in the electronic device to which the image sensor is applied. The image sensor may be electrically connected to one or more or all of the passive elements. Since the test module 100 includes the image sensor and at least one of the plurality of passive elements, the test module 100 may more accurately test the performance of the image sensor.

For example, when the image sensor is coupled to a plastic leadless chip carrier (PLCC) to test the performance of the image sensor, the area and shape of the PLCC may remain constant regardless of those of the image sensor. However, the electrical environment in the electronic device to which the image sensor is applied may vary. The electrical environment may refer to passive elements that are included in the electronic device and affect the operation of the image sensor. Therefore, when testing the performance of the image sensor based on the PLCC, there may be limits to test accuracy. For example, when testing the performance of the image sensor based on the PLCC, the wiring length, the location of passive elements (e.g., capacitors), and the presence or absence of an infrared cut filter (IRCF) may be different from those in the electronic device to which the image sensor is applied. Therefore, testing of the performance of the image sensor based on the PLCC may not be performed accurately. Alternatively or additionally, when testing the image sensor based on a printed circuit board (PCB) containing the image sensor and passive elements to accurately reflect the electrical environment in the electronic device, it may take significant cost and/or significant time to produce a test socket combinable with a test module.

The test module 100 according to inventive concepts may have a constant area and/or shape regardless of those of the image sensor, and may include at least one of the plurality of passive elements included in the electronic device to which the image sensor is applied. Accordingly, since it may be possible to relatively accurately test the performance of an image sensor based on the test module 100 according to inventive concepts and test a plurality of image sensors having different areas and/or shapes based on the test socket 200 according to inventive concepts, the cost and/or the time required to test the performance of image sensors may be reduced.

FIG. 2 is a perspective view of a test module according to various example embodiments.

Referring to FIG. 2, a test module 100a according to inventive concepts may include a test board 110a, a flexible printed circuit board (FPCB) 120a, a connector 130a, an image sensor 140a, and an infrared cut filter 150a.

The test board 110a may refer to a board on which a PCB design can be performed. For example, the PCB design may be performed on some regions of the test board 110a according to inventive concepts (e.g., coupled to an image sensor), and the PCB design may not be performed on the other regions thereof.

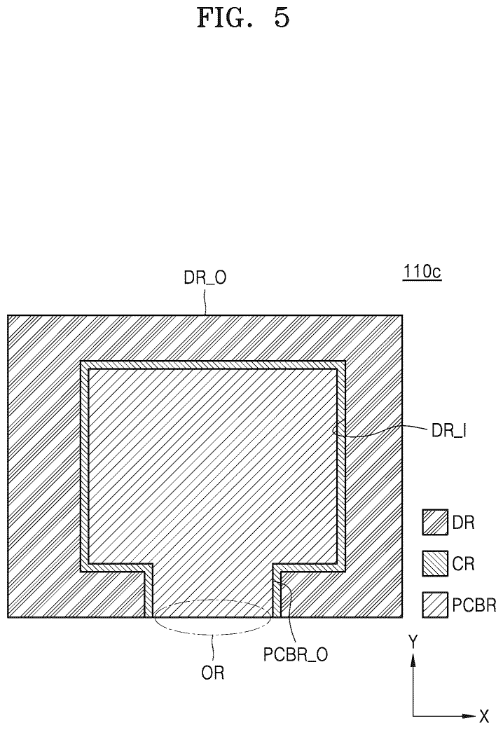

The test board 110a according to inventive concepts may include a PCB region, a cut-off region, and a dummy region, which are described below. On the test board 110a, the PCB region may refer to a region where an image sensor and/or at least one passive element are formed (or combined), and the dummy region may refer to a region where the PCB has not been designed. The cut-off region may refer to a region that electrically separates or electrically insulates the PCB region from the dummy region. The dummy region may be electrically cut off or insulated from the image sensor by the cut-off region. Therefore, the dummy region may not affect the image signal generated by the image sensor. Since the test board 100a according to inventive concepts has the dummy region, the test board 100a may have a constant area and shape regardless of the area and shape of the image sensor. The test board 110a is described in more detail below with reference to FIG. 5.

As described above, the image sensor and/or at least one passive element may be formed on the test board 100a. Accordingly, the area of the test board 100a according to inventive concepts may be sufficient to allow the image sensor to be coupled thereto. For example, the area of the test board 100a may be greater than the area of the image sensor, the length of the test board 100a in a first direction (X direction) may be 1 inch (2.54 cm) or less, and the length of the test board 100a in a second direction (Y direction) perpendicular to the first direction (X direction) may be 2.54 cm (1 inch) or less. In some example embodiments, a shape of the test board 110a may be rectangular, e.g., square; however, example embodiments are not limited thereto.

The FPCB 120a may refer to a FPCB which is the same as a camera module including the image sensor.

The connector 130a may be connected between the FPCB 120a and the test socket (200 in FIG. 1). The connector 130a may receive the image signal (IS in FIG. 1) generated from the image sensor 140a through the FPCB 120a, and may transmit the image signal (IS in FIG. 1) to the test socket (200 in FIG. 1). The connector 130a may receive an electrical signal from the test socket (200 in FIG. 1) and/or the computer (300 in FIG. 1) to generate the image signal from the image sensor 140a.

The image sensor 140a may be physically and/or electrically coupled to the test module 100a as described above with reference to FIG. 1. The image sensor 140a may be coupled to the top of the test board 110a (in Z direction). The image sensor 140a may include various components such as a pixel array, a row driver, a ramp signal generator, a counting code generator, an analog-to-digital converter, a data output circuit, and a timing controller; example embodiments are not limited thereto. The pixel array is connected to a plurality of row lines, a plurality of column lines, and a plurality of row lines and a plurality of column lines, and includes a plurality of pixels arranged in rows and columns. Each of the plurality of pixels may include at least one photoelectric converter such as but not limited to a photodiode, and may sense light using the photoelectric converter and output an image signal, which is an electrical signal according to the sensed light. The test module 100a according to inventive concepts may receive the image signal from the image sensor, and may transmit the image signal to the computer (300 in FIG. 1) through the test socket (200 in FIG. 1). The computer (300 in FIG. 1) may test the performance of the image sensor based on the image signal generated from the image sensor coupled to the test module 100a according to inventive concepts.

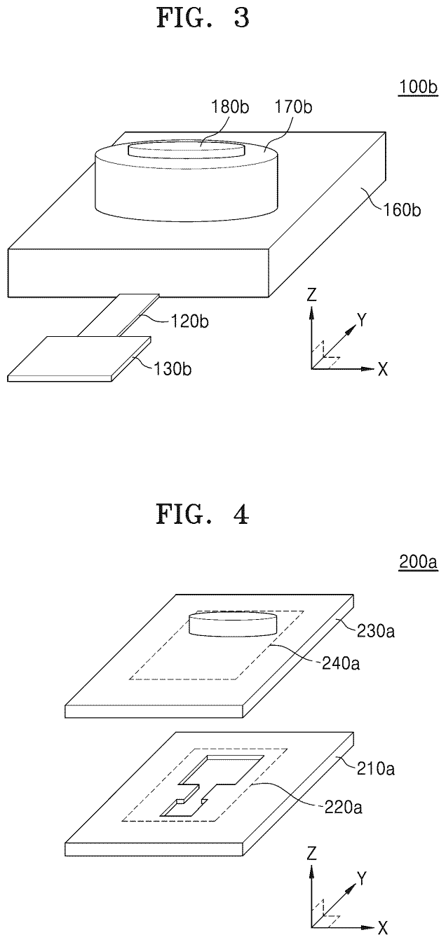

The infrared cut filter 150a may be located on the top of the image sensor 140a coupled to the test board 110a. The infrared cut filter 150a may be included in the electronic device to which the image sensor is applied and may relatively accurately reproduce the color of a subject by blocking infrared rays. For example, an image sensor of a digital camera may react unnecessarily not only to visible light but also to light in the infrared band, thereby reducing its ability to reproduce the original color of the subject. To prevent or reduce the impact of this problem, the infrared cut filter 150a may be applied to the electronic device. The test module 100a according to inventive concepts may include the infrared cut filter 150a to reflect the optical environment in the electronic device to which the image sensor 140a is applied when testing the performance of the image sensor 140a. The optical environment may refer to an optical configuration included in the electronic device to which the image sensor is applied. For example, the electronic device may include the infrared cut filter 150a and a lens as described above, and the infrared cut filter 150a and the lens may have an optical effect on the image signal generated by the image sensor. Accordingly, the test module 100a according to inventive concepts may include at least one of the infrared cut filter 150a and the lens included in the electronic device to accurately test the performance of the image sensor. The test module (100b in FIG. 3) including the lens is described below with reference to FIG. 3.

Although not shown in FIG. 2, the test module 100a according to inventive concepts may further include a cover glass to protect the test board 110a and the image sensor 140a from foreign substances.

FIG. 3 is a perspective view of a test module according to various example embodiments.

Referring to FIG. 3, a test module 100b according to inventive concepts may include a FPCB 120b, a connector 130b, a housing 160b, a barrel 170b, and a lens 180b.

Since the FPCB 120b and connector 130b of FIG. 3 correspond to the FPCB 120a and the connector 130a described with reference to FIG. 2, overlapping descriptions are omitted. In addition, description below is made on the assumption that the test board (110a in FIG. 2) described with reference to FIG. 2 and the image sensor (140a in FIG. 2) coupled to the test board (110a in FIG. 2) are located inside the housing 160b even though it is omitted for the convenience of expression.

The housing 160b according to inventive concepts may be coupled to the test board. The housing 160b may be coupled to the barrel 170b upon which a lens can be mounted. The test board according to inventive concepts may have a constant area and constant shape regardless of the area and/or a shape of the image sensor. Since the test board has a constant area and shape regardless of those of the image sensor, the housing 160b coupled with the test board may have a constant area and shape regardless of those of the image sensor. Therefore, since the housing 160b according to inventive concepts is used to test the performance of each of a plurality of image sensors having different areas and/or shapes, the cost and/or the time required to test the performance of the image sensors may be reduced.

The housing 160b may include the infrared cut filter described with reference to FIG. 2.

The barrel 170b may be coupled to the top of the housing 160b (in Z direction). The barrel 170b may be coupled to the lens 180b included in the electronic device to which the image sensor is applied. Accordingly, when testing the image sensor, the lens 180b may be coupled to the barrel 170b to reflect the optical environment in the electronic device to which the image sensor is applied.

The barrel 170b according to inventive concepts may be coupled to a first lens applied to the electronic device to which a first image sensor is applied and a second lens applied to the electronic device to which a second image sensor is applied. For example, when testing the performance of the first image sensor, the first lens may be coupled to the barrel 170b, and when testing the performance of the second image sensor, the second lens may be coupled to the barrel 170b.

The lens 180b may form an optical image on the image sensor by focusing light reflected from the subject. The optical image formed on the image sensor may vary depending on the lens 180b. For example, one or more of the size, ratio, intensity of light, etc. of the optical image formed on the image sensor may vary depending on the lens 180b. Therefore, to accurately or more accurately test the performance of the image sensor, it is necessary or desirable to test the performance of the image sensor based on the lens 180b applied to the electronic device.

FIG. 4 is a perspective view of a test socket according to various example embodiments.

Referring to FIG. 4, a test socket 200a according to inventive concepts may include a first coupler 210a and a second coupler 230a.

The first coupler 210a according to inventive concepts may include a first coupling region 220a that can be physically coupled to the test module, and the second coupler 230a may include a second coupling region 240a that can be physically coupled to the test module.

The test socket 200a may be physically and/or electrically coupled to the test module through the first coupling region 220a and the second coupling region 240a included in the first coupler 210a and the second coupler 230a, respectively. Specifically, the test module may be coupled to the test socket 200a by coupling the first coupler 210a to the second coupler 230a.

For convenience of explanation, it is illustrated that the test socket 200a of FIG. 4 includes the first coupler 210a including the first coupling region 220a and the second coupler 230a including the second coupling region 240a, but is not limited thereto. For example, the test socket 200a may further include a contact pin terminal that can be electrically coupled to a connector included in the test module. Alternatively or additionally, the test socket 200a may further include a fixing unit for coupling and fixing the first coupler 210a to the second coupler 230a. It is illustrated in FIG. 4 that the first coupler 210a is separated from the second coupler 230a, but the test socket 200a may further include a rotator (not shown) connected to each of the first coupler 210a and the second coupler 230a on one side of each of the first coupler 210a and the second coupler 230a. The first coupler 210a and the second coupler 230a may be coupled to and separated from each other by rotation of the rotator; in some example embodiments, the rotator may be threaded, however example embodiments are not limited thereto. The test socket 200a may further include a controller capable of determining operations, such as generating an image signal and/or transmitting the image signal to the computer (300 in FIG. 1). The test socket 200a may further include a connection terminal electrically connected to the computer (300 in FIG. 1), and may transmit the image signal generated by the image sensor to the computer (300 in FIG. 1) through the connection terminal. For convenience of explanation, it is illustrated in FIG. 4 that the area and shape of the first coupler 210a are expressed as similar to or the same as those of the second coupler 230a, but is not limited thereto. The area and/or the shape of the first coupler 210a may be different from those of the second coupler 230a.

The test module may be located between the first coupler 210a and the second coupler 230a, and may be fixed and coupled to the test socket 200a when the first coupler 210a is coupled to the second coupler 230a. For example, the test module 100b of FIG. 3 may be located between the first coupler 210a and the second coupler 230a, and may be fixed and coupled to the test socket 200a when the first coupler 210a is coupled to the second coupler 230a. The first coupling region 220a and the second coupling region 240a may have a recessed structure that reflects the area and shape of the test module so that first coupling region 220a and the second coupling region 240a are coupled to the test module. For example, the first coupling region 220a may have a recessed region corresponding to the area and shape of the housing (160b in FIG. 3), FPCB (120b in FIG. 3), and connector (130b in FIG. 3) described with reference to FIG. 3. The second coupling region 240a may have a recessed structure corresponding to the area and shape of the barrel (170b in FIG. 3) described with reference to FIG. 3.

Referring to the above, the test socket 200a according to inventive concepts may have a recessed structure such that the test socket 200a is coupled to a first test module that is coupled to a first image sensor through a first test board. Since the test socket 200a has the recessed structure, the test socket 200a may be coupled with a second test module coupled to a second image sensor through a second test board. Since the area and shape of the first test board may be the same as those of the second test board, the first test module and the second test module may have the same area and shape. Accordingly, the shape of the first test module and the second test module may correspond to the recessed structure. For example, the test socket 200a may be coupled to the first test module and the second test module. Accordingly, the performance of the first image sensor and the second image sensor having different areas may be tested based on one test socket 200a.

Since the test socket 200a according to inventive concepts is used to test the performance of image sensors having different areas and/or different shapes, the cost and time required or used to test the performance of the image sensors may be reduced. For example, since there is no need to manufacture a separate test socket to test the performance of image sensors having different areas and/or shapes, the cost and/or the time to test the performance of the image sensors may be reduced.

FIG. 5 is a plan view of a test board according to various example embodiments.

Referring to FIG. 5, a test board 110c according to inventive concepts may include a PCB region PCBR, a cut-off region CR, and a dummy region DR.

An outer perimeter DR_O of the dummy region DR may be formed along the perimeter of the test board 110c. As described above, the length of the test board 110c in the first direction (X direction) may be 2.54 cm (1 inch) or less, and the length of the test board 110c in the second direction (Y direction) perpendicular to the first direction (X direction) may be 2.54 cm (1 inch) or less. Accordingly, the length of the outer perimeter DR_O of the dummy region DR in the first direction (X direction) may be 2.54 cm (1 inch) or less, and the length thereof in the second direction (Y direction) perpendicular to the first direction (X direction) may be 2.54 cm (1 inch) or less.

The dummy region DR according to inventive concepts may be a region including copper, but is not limited thereto.

The PCB region PCBR according to inventive concepts may refer to a region including an image sensor as described above. As described above, the PCB region PCBR may further include at least one passive element among the plurality of passive elements included in the electronic device to which the image sensor is applied. The image sensor and the one passive element included in the PCB region PCBR may be electrically connected to each other. As the at least one passive element is included in the PCB region PCBR, an image signal similar to the image signal generated by the electronic device to which the image sensor is applied may be generated. For example, the image signal that reflects the electrical environment in the electronic device to which the image sensor is applied may be generated, and the performance of the image sensor may be tested more accurately.

As described above, since the PCB region PCBR includes the image sensor, the PCB region PCBR according to inventive concepts may be determined based on the area of the image sensor. For example, the area of a first PCB region of the first test board coupled with the first image sensor having a first area may be greater than the area of a second PCB region of the second test board coupled with the second image sensor having an area smaller than the first area, but is not limited thereto. For example, the area of the PCB region PCBR may vary depending on not only the area of the image sensor but also the number and area of passive elements included in the PCB region PCBR.

The PCB region PCBR according to inventive concepts may include an output region (OR). The output region OR may be connected to the FPCB (120b in FIG. 3) described with reference to FIG. 3. The image sensor included in the PCB region PCBR may generate an image signal, and may transmit the image signal to the connector (130b in FIG. 3) through the output region OR.

The cut-off region CR according to inventive concepts may be located between the dummy region DR and the PCB region PCBR. The outer perimeter of the cut-off region CR may be an inner perimeter DR_I of the dummy region DR, and the inner perimeter of the cut-off region CR may be an outer perimeter PCBR_O of the PCB region PCBR. As described above, the cut-off region may be located between the dummy region DR and the PCB region PCBR, and may electrically cut off the dummy region DR from the PCB region PCBR. For example, the cut-off CR may include an insulator such as but not limited to plastic and/or rubber and/or glass.

As described above, through the recessed structure, the test socket (200a in FIG. 4) according to inventive concepts may be coupled to at least one of the first test module coupled to the first image sensor having a first area through the first test board and the second test module coupled to the second image sensor having a second area different from the first area through the second test board. According to inventive concepts, the areas of the first dummy region, the first PCB region, and the first cut-off region included in the first test board may be different from any one of the areas of the second dummy region, the second PCB region, and the second cut-off region included in the second test board. For example, the first image sensor and the second image sensor may have different areas, and accordingly, the area of the first PCB region may be different from the area of the second PCB region. Furthermore, since the first test board and the second test board may have the same area, the area of the first dummy region may be different from the area of the second dummy region.

Therefore, since the test board 110c according to inventive concepts includes the dummy region DR and the cut-off region CR, the test board 110c may have a constant area and shape regardless of the area and shape of the image sensor. The area of the test board 110c may be greater than the area of the image sensor so that the test board 110c has a constant area and shape regardless of the area and shape of the image sensor. Accordingly, since there is no need or desire to separately manufacture a housing, barrel, and a test socket to test the performance of the image sensor, the cost and time required to test the performance of the image sensor may be reduced.

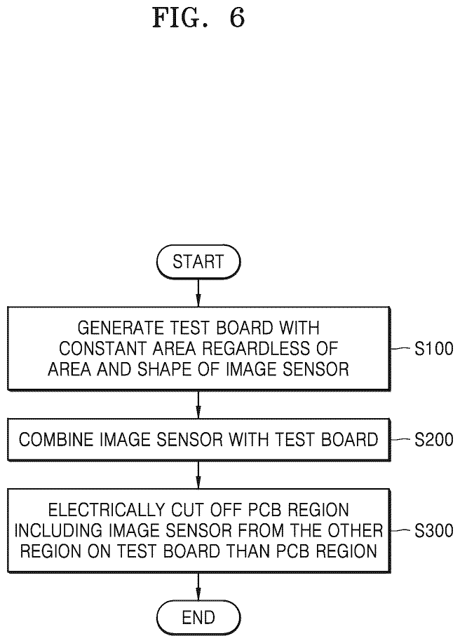

FIG. 6 is a flowchart of a method of manufacturing a test module according to various example embodiments.

Referring to FIG. 6, in operation S100, the method of manufacturing a test module according to inventive concepts may generate a test board having a constant area regardless of the area and shape of the image sensor. For example, the test board may be an insulation board having a constant area regardless of the area of the image sensor.

In operation S200, the image sensor may be coupled to the test board. A certain region including the image sensor on the test board may be referred to as the PCB region. For example, the image sensor may be coupled to the top of the test board, and the passive elements contained in the electronic device to which the image sensor is applied may be coupled on the test board. The image sensor coupled to the top of the test board may be electrically connected to the passive elements through wiring.

In operation S300, the cut-off region may be formed to electrically cut off the PCB region including the image sensor from the other region on the test board than the PCB region. As described above, the test board may include the dummy region electrically cut off from the PCB region. The PCB region may be electrically cut off from the dummy region by the cut-off region.

The outer perimeter of the PCB region may be the same as the inner perimeter of the cut-off region. The PCB region may be electrically connected to the FPCB and the connector, and the image signal generated from the image sensor may be transmitted to the test socket through the FPCB and the connector.

As described above, when testing the performance of the image sensor, at least one passive element among the plurality of passive elements included in the electronic device to which the image sensor is applied may be electrically coupled to the PCB region to reflect the electrical environment in the electronic device to which the image sensor is applied. Accordingly, the at least one passive element may be electrically connected to the image sensor. Since the test module includes the at least one passive element, the test system according to inventive concepts may more accurately test the performance of the image sensor by reflecting the electrical environment in the electronic device to which the image sensor is applied.

Alternatively or additionally, as described above, a lens may be located on the top of the image sensor coupled to the test board. Since the test module includes the lens, the test system according to inventive concepts may more accurately test the performance of the image sensor by reflecting the optical environment in the electronic device to which the image sensor is applied.

Alternatively or additionally, as described above, since the performance of each of a plurality of different image sensors is tested based on one test socket, the cost and time required to test the performance of the image sensors may be reduced.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While various inventive concepts have been particularly shown and described with reference to embodiments thereof, it will be understood that various changes in form and details may be made therein without departing from the spirit and scope of the following claims.

What is claimed is:

1. A test module configured to test the performance of an image sensor, the test module comprising:
a test board having an area greater than an area of the image sensor and configured to be coupled to the image sensor; and
a connector electrically connected to the image sensor and configured to transmit an electrical signal received from the image sensor to a test socket,
wherein the test board comprises:
a dummy region of which an outer perimeter corresponds to a perimeter of the test board, the dummy region configured to be electrically cut off from the image sensor; and
a cut-off region corresponding to an inner perimeter of the dummy region, between the dummy region and the image sensor, and configured to electrically cut off the dummy region from the image sensor.

2. The test module of claim 1, wherein the test board further comprises a printed circuit board (PCB) region corresponding to an inner perimeter of the cut-off region and configured to be coupled to the image sensor.

3. The test module of claim 2, wherein an area of the PCB region is based on the area of the image sensor.

4. The test module of claim 2, wherein the PCB region comprises the image sensor and at least one passive element from among a plurality of passive elements included in an electronic device to which the image sensor is configured to be applied.

5. The test module of claim 2, further comprising:
a flexible printed circuit board (FPCB) electrically connected to the connector and configured to receive and transmit an image signal generated by the image sensor, the receiving and transmitting being from and to the connector.

6. The test module of claim 2, wherein the cut-off region is between the dummy region and the PCB region.

7. The test module of claim 2, wherein the cut-off region is configured to electrically cut off the dummy region from the PCB region.

8. The test module of claim 2, further comprising:
an infrared cut filter configured to block infrared rays.

9. The test module of claim 1, wherein each of lengths of the test board in a first direction and in a second direction perpendicular to the first direction is 2.54 cm or less.

10. The test module of claim 1, further comprising:
a barrel on top of the test board and configured to allow a lens applied to an electronic device to which the image sensor is applied to be detachable.

11. The test module of claim 10, further comprising:
the lens, wherein the lens is attached to the barrel.

12. A test system comprising:
a first test module comprising a first test board and configured to be coupled to a first image sensor through the first test board, the first sensor having a first area; and
a test socket comprising a coupling region having a recessed structure corresponding to a shape of the first test module, and configured to be coupled to the first test module through the coupling region,
wherein the first test board comprises:
a first dummy region corresponding to a perimeter of the first test board,
a first printed circuit board (PCB) region configured to be coupled to the first image sensor, and
a first cut-off region between the first dummy region and the first PCB region and configured to electrically cut off the first dummy region from the first PCB region.

13. The test system of claim 12, wherein the test socket is configured to be coupled to a second test module coupled to a second image sensor through the coupling region, the second image sensor having a second area different from the first area.

14. The test system of claim 13, further comprising:
a second test board, wherein
the second test module is configured to be coupled to the second image sensor through the second test board, and
wherein the second test board comprises:
a second dummy region corresponding to a perimeter of the second test board;
a second PCB region configured to be couple d to the second image sensor, and
a second cut-off region between the second dummy region and the second PCB region and configured to electrically cut off the second dummy region from the second PCB region.

15. The test system of claim 14, wherein the first PCB region and the second PCB region are different from each other in at least one of an area or a shape.

16. The test system of claim 14, wherein the first test board and the second test board have a same area and a same shape.

17. The test system of claim 13, further comprising:
a barrel configured to allow a first lens applied to an electronic device to which the first image sensor is applied to be detachable.

18. The test system of claim 17, wherein the barrel is configured to allow a second lens different from the first lens and applied to an electronic device to which the second image sensor is applied to be detachable.

19. A test module configured to test the performance of an image sensor, the test module comprising:
a test board having an area greater than an area of the image sensor and configured to be coupled to the image sensor; and
a connector electrically connected to the image sensor and configured to transmit an electrical signal received from the image sensor to a test socket,
wherein the test board comprises:
a printed circuit board (PCB) region configured to be coupled to the image sensor; and
a cut-off region configured to electrically cut off the PCB region from the other region of the test board than the PCB region.

20. The test module of claim 19, wherein the PCB region comprises the image sensor and at least one passive element among a plurality of passive elements included in an electronic device to which the image sensor is applied.
